(19) United States
(12) Patent Application Publication
(10) Pub. No.: US 2013/0105662 A1
(43) Pub. Date: May 2, 2013

(54) Easily Attachable/Detachable, Multi-Function Support For A Tablet Personal Computer

(71) Applicant: Ryan E. Cote, Blacklick, OH (US)

(72) Inventor: Ryan E. Cote, Blacklick, OH (US)

(73) Assignee: THE GRABLET, LLC, Columbus, OH (US)

(21) Appl. No.: 13/328,695

(22) Filed: Dec. 16, 2011

Related U.S. Application Data
(63) Continuation-in-part of application No. 29/405,420, filed on Nov. 2, 2011, now Pat. No. D674804.

(51) Int. Cl. H05K 7/00

(52) U.S. Cl. 248/689

(57) ABSTRACT

An elastically deformable base is configured to seat against the back of a tablet computer. Four arms extend diagonally outwardly from a central portion of the base around and against the sides of the computer and toward its corners. The arms each have an inwardly directed flange extending onto the edge of the face of the computer for retaining the computer against the base. The base also has a plurality of releasable, base mounted strap connectors at spaced-apart attachment points on the base. A pair of straps is connected to the base. Each strap has at least two, strap mounted connectors that mate with the base mounted strap connectors and detachably attach the strap to the base.

### CROSS-REFERENCES TO RELATED APPLICATIONS

This application is a continuation-in-part of, and claims the benefit of, U.S. Design Patent Application No. 29/405,420 filed Nov. 2, 2011 and now pending.

### STATEMENT REGARDING FEDERALLY-SPONSORED RESEARCH AND DEVELOPMENT

(Not Applicable)

### REFERENCE TO AN APPENDIX

(Not Applicable)

### BACKGROUND OF THE INVENTION

This invention relates to devices for assisting a user support hand held objects and more particularly relates to a device for facilitating the hand support of an electronic device, especially a tablet computer, in a manner that provides a more comfortable and more secure grip by the user's hand both during use and during transport and alternatively allows convenient hanging of the computer from an inanimate object or the user's body.

Portable personal computers have become popular and versatile tools for millions of people throughout the world. They have been developed into compact personal computers that are easily carried by hand and conveniently used in nearly any environment. Part of their convenience is that their size permits them to be used while resting on a persons lap, or held in a user's hands or on a small table.

Unfortunately, one of the undesirable consequences of their small size and streamlined contour is that they can be difficult to hold and retain in an orientation that is comfortable and convenient for the user while being operated. Additionally it is not only desirable to support the computer in a comfortable orientation for use, but it is also desirable to support the computer in a manner that is secure against being dropped or being struck by another object or person. For example, because of their small size and smooth, streamlined contour, they can easily and unexpectedly fall from a person's lap onto a hard floor and suffer substantial and expensive or even fatal damage. At times, some users would like to hang the computer on a wall or other object where they can still be viewed and used and/or to suspend them in a relatively safe location away from human traffic.

It is therefore an object and feature of the invention to provide a support that easily attaches to a portable personal computer, especially a table personal computer, and has straps and other means associated with the support that are convenient for being gripped or held by human hands.

Another object and feature of the invention is to provide a relatively simple support that uses the same structures for supporting the computer in a variety of other ways than by human hands.

Yet another object of the invention is to provide a support that, despite its simplicity, affords that user a broad variety of configuration choices so the user can configure the support to suit the personal preferences of the user.

Still another object of the invention is to provide a support that is easy to assemble in the user's desired configuration.

### BRIEF SUMMARY OF THE INVENTION

The invention is a multi-function support for a tablet personal computer which is generally rectangular and has a back, sides and a front face. The support has an elastically deformable base configured to seat against the back of the tablet computer. The base has a plurality of arms, each arm extending outwardly from a central portion of the base toward the sides of the computer and further extending around and against spaced apart portions of the sides of the computer. The ends of the arms each have an inwardly directed flange extending onto the edge of the face of the computer for retaining the computer against the base. Preferably, the base has four arms diagonally extending toward four corners of a rectangle representing the computer and the face engaging flanges of each arm extend along a right angle for engaging the computer face around each corner of the tablet computer. The base also has a plurality of releasable, base mounted, strap connectors at spaced-apart attachment points on the base. At least one strap and preferably two straps are connected to the base. Each strap has at least two, strap mounted strap connectors that mate with the base mounted strap connectors and detachably attach the strap to the base. Each strap has a length greater than the distance between attachment points.

### BRIEF DESCRIPTION OF THE SEVERAL VIEWS OF THE DRAWINGS

FIG. 1 is a view in perspective of the top or front of the preferred embodiment of the invention with a tablet personal computer mounted to the embodiment.

FIG. 2 is a view in the same perspective as FIG. 1 but with the tablet personal computer removed.

FIG. 3 is a view in perspective of the bottom or back of the embodiment of FIG. 1 with the computer mounted to the embodiment.

FIG. 4 is a view in the same perspective as FIG. 3 but with the tablet personal computer removed.

FIG. 5 is a top or plan view of the embodiment illustrated in FIG. 1.

FIG. 6 is a bottom or back view of the embodiment illustrated in FIG. 1.

FIG. 7 is an end view of the embodiment illustrated in FIG. 1.

FIG. 8 in an end view of the opposite end of the embodiment illustrated in FIG. 1.

FIG. 9 is a side view of the embodiment illustrated in FIG. 1.

FIG. 10 is a side view of the opposite side of the embodiment illustrated in FIG. 1.

FIG. 11 is a top or plan view of the embodiment illustrated in FIG. 1 and illustrating in dotted lines the alignment of the side edges of a tablet personal computer mounted to the embodiment of FIG. 1.

FIG. 12 is an end view of the embodiment illustrated in FIG. 1 and illustrating in dotted lines the alignment of the side edges of a tablet personal computer mounted to the embodiment of FIG. 1.

FIG. 12A is an enlarged view in section, taken along the line 12A-12A in FIG. 11 illustrating the flange that extends over the front face of the computer.

FIG. 13 is an exploded view showing the base, the straps and the hand pad of the embodiment illustrated in FIG. 1.

FIG. 14 is a view in perspective of the underside of the straps and the hand pad illustrated in FIG. 13.

FIG. 15 is an enlarged view in perspective illustrating a strap mounted strap connector forming a part of the embodiment illustrated in FIG. 1.

In describing the preferred embodiment of the invention which is illustrated in the drawings, specific terminology will be resorted to for the sake of clarity. However, it is not intended that the invention be limited to the specific term so selected and it is to be understood that each specific term includes all technical equivalents which operate in a similar manner to accomplish a similar purpose.

### DETAILED DESCRIPTION OF THE INVENTION

The preferred embodiment of the invention is illustrated in the several figures along with some views of its component parts. This description is directed generally to all of the figures in which the identical parts are designated by identical reference numerals. Reference is made to a particular figure when a figure best illustrates a particular structure.

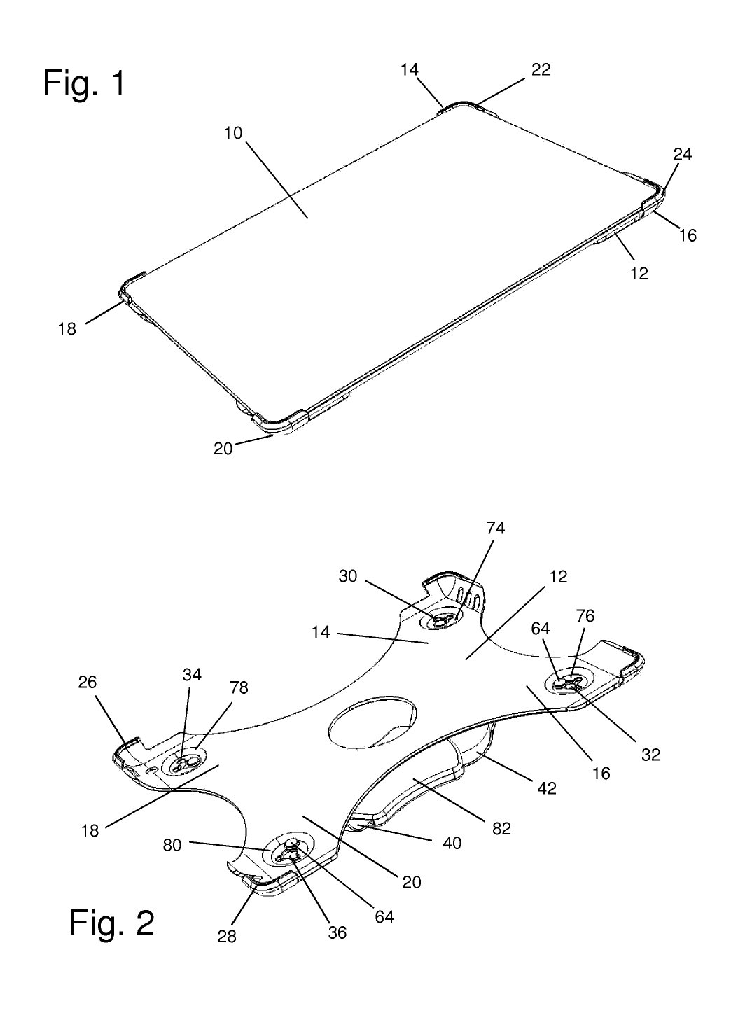

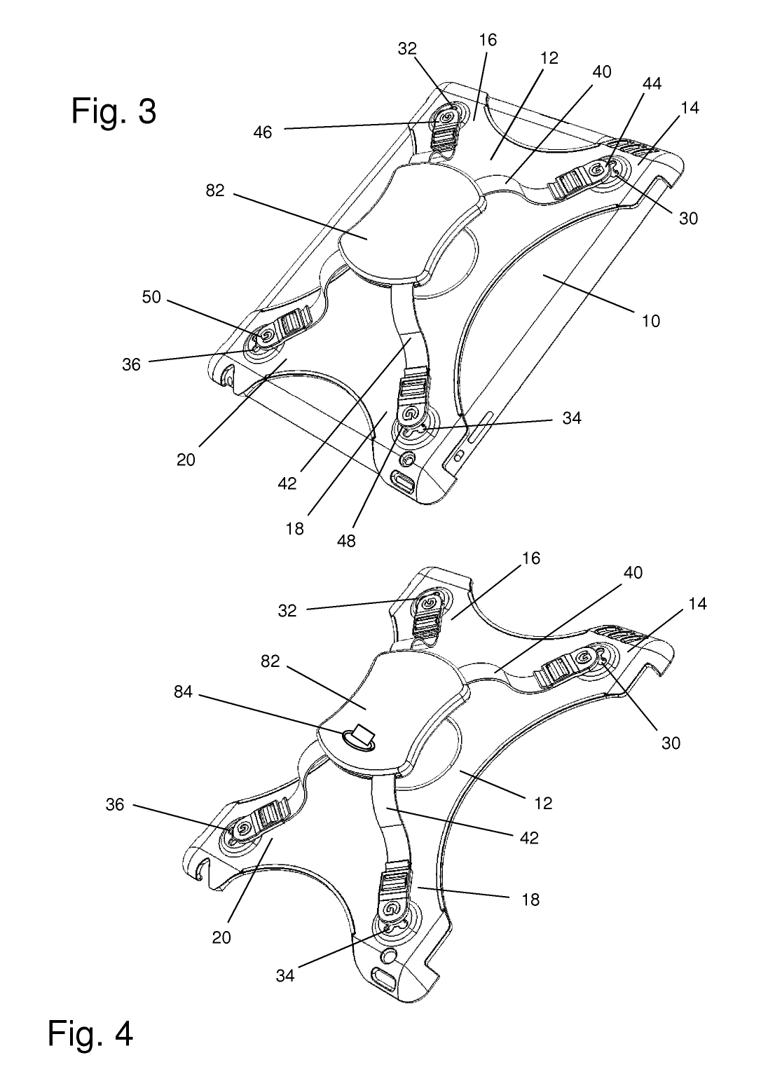

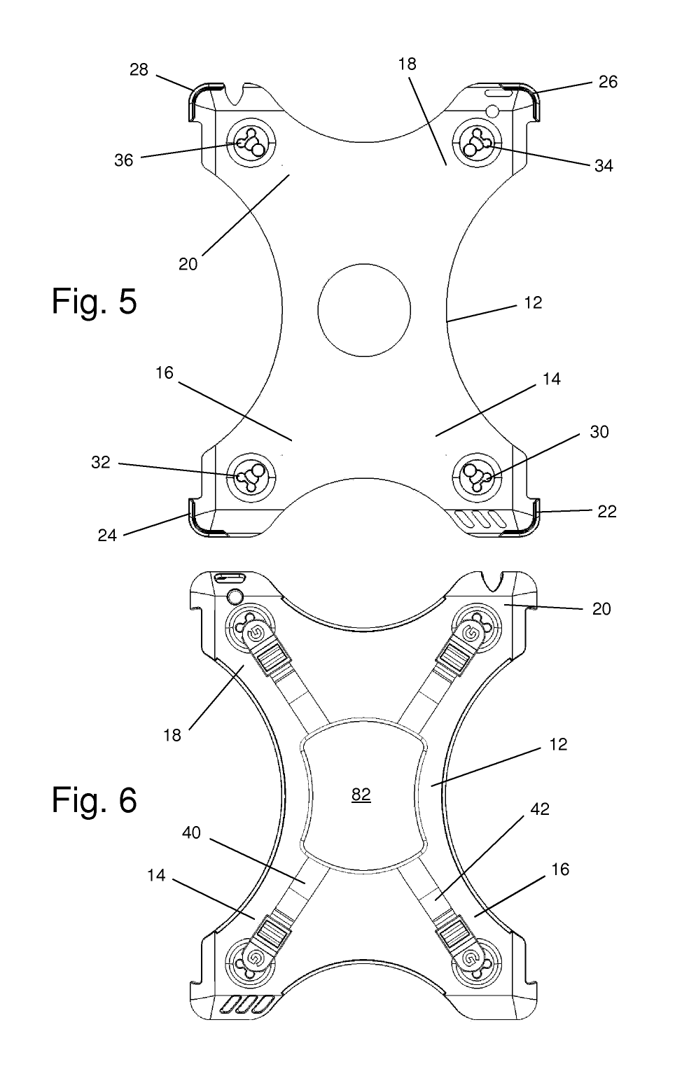

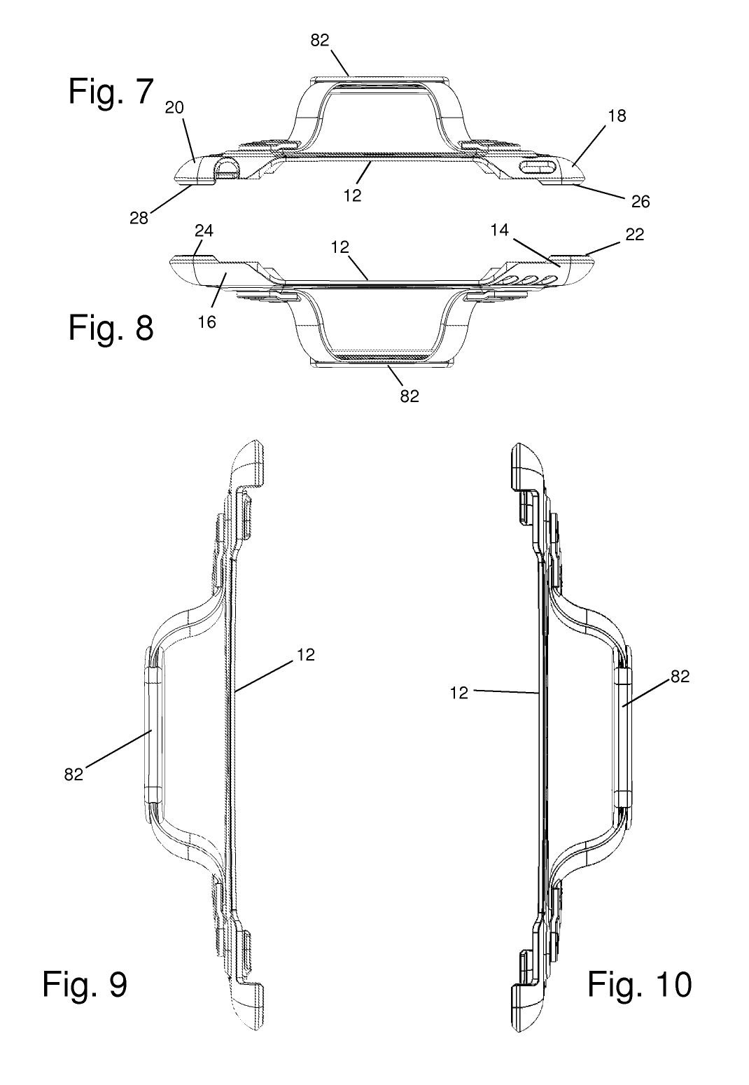

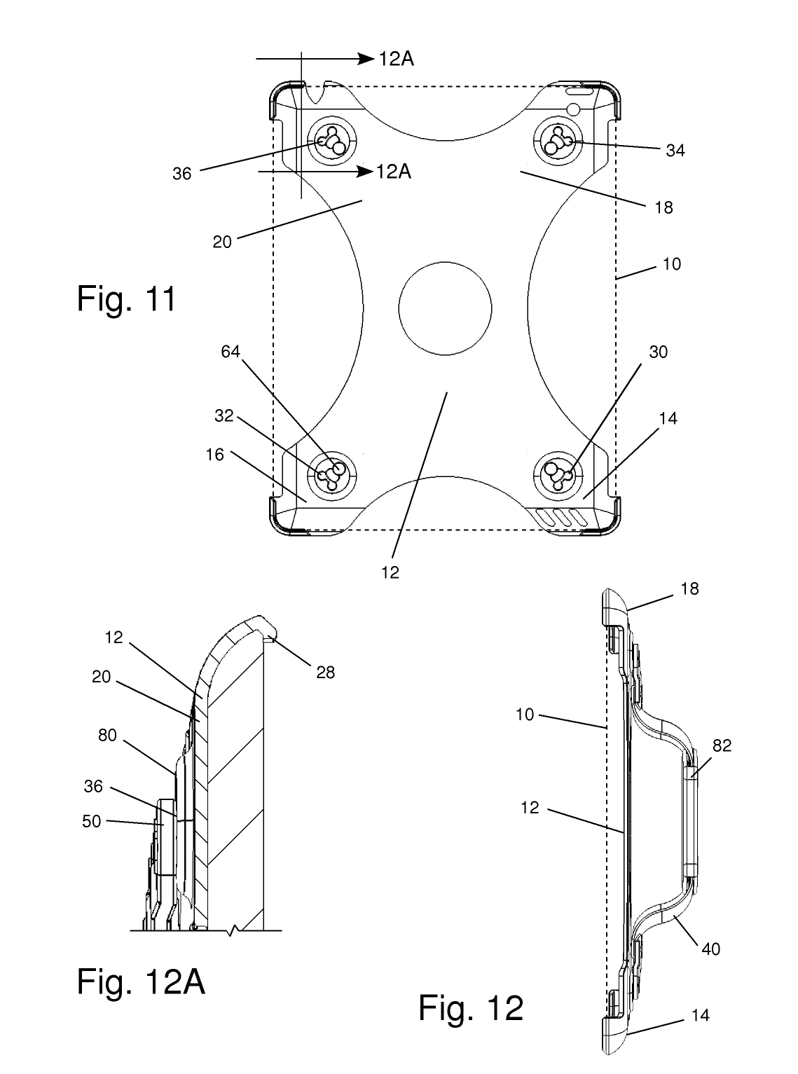

The invention is a multi-function support for a tablet personal computer although it can also be used for other computers or other objects that have structural features which can mate with the gripping structures of the multi-function support. A tablet computer has a generally rectangular shape with a back, four sides and a front face that is generally planar, at least around its edges. A tablet computer 10 is illustrated in FIGS. 1, 3, and 12A and its location is shown in dashed lines in FIGS. 11 and 12. The preferred embodiment of the invention is designed and particularly suited for use with an Apple® iPad®.

### Preferred Structural Features

The multi-function support of the invention has an elastically deformable base 12 configured to conformingly seat flat against the back of the computer 10 and its curved sides. Preferably the base is made of thermoplastic polyurethane which is highly durable, has excellent abrasion resistance, outstanding low-temperature performance and a desirable combination of mechanical strength with rubber-like high elasticity. The base 12 includes a plurality of arms 14, 16, 18 and 20. Each of these arms extends outwardly from a central portion of the base 12 toward the sides of the computer 10 and then continues around and against spaced apart portions of the sides of the computer 10. Preferably, the base has four arms diagonally extending toward four corners of a rectangle that represents the rectangular computer. It is also preferred that the base and its arms conformingly extend along and against the surface of the back and sides of the computer so that the computer is tightly seated against the base. This assures that the computer is securely held in the base and also allows the computer and base to be comfortably held and carried in the manner of a book.

Formed at the end of each of the arms is a flange extending inwardly onto the edge of the face of the computer for retaining the computer against the base. These flanges 22, 24, 26 and 28 seat against the rim of the front face of the computer. The arms 14-20 are preferably aligned along diagonals of the rectangular computer so that the face engaging flanges 22-28 at their ends can be configured as a right angle which allows them to engage the face of the computer around each corner of the computer. Several small ports and cutouts are formed through the base, particularly near the ends of the arms where the arms follow the contour of and seat against the sides of the computer. These ports and cutouts allow user access to connectors and switches of the computer.

The base 12 also has a plurality of releasable, base mounted strap connectors 30, 32, 34 and 36 at spaced-apart attachment points on the base 12. As described in more detail below, the purpose of the base mounted strap connectors is allow one or more straps to be easily connected and disconnected to the base 12 in a variety of alternative configurations for various functional purposes and user preferences. The straps 40 and 42 have a length greater than the distance between the attachment points at the base mounted strap connectors 30-36 and preferably have an adjustable length about 12 inches long to allow insertion of a user's hand between the straps 40 and 42 and the base 12. Each strap has at least two, strap mounted strap connectors, one near each opposite end of the strap. The straps 40 and 42 have strap mounted connectors 44, 46, 48 and 50 and these strap connectors 44-50 mate with the base mounted strap connectors 30-36 in order to detachably attach the straps 40 and 42 to the base 12.

FIG. 15 illustrates the preferred strap mounted connector 48 which is identical to the others. As known in the art of adjustably connecting a flexible strap to a rigid fitting, the strap connector 48 has spaced crossbars 52 and 54 with interposed slots through which the strap is fed and then pulled tight at its desired length. In the preferred embodiment of the invention, each of the strap mounted connectors comprises a T-shaped post 60 having a rod 62 connected to a strap at one end and having a cap 64 at the opposite end. The cap 64 has a greater diameter or width than the rod.

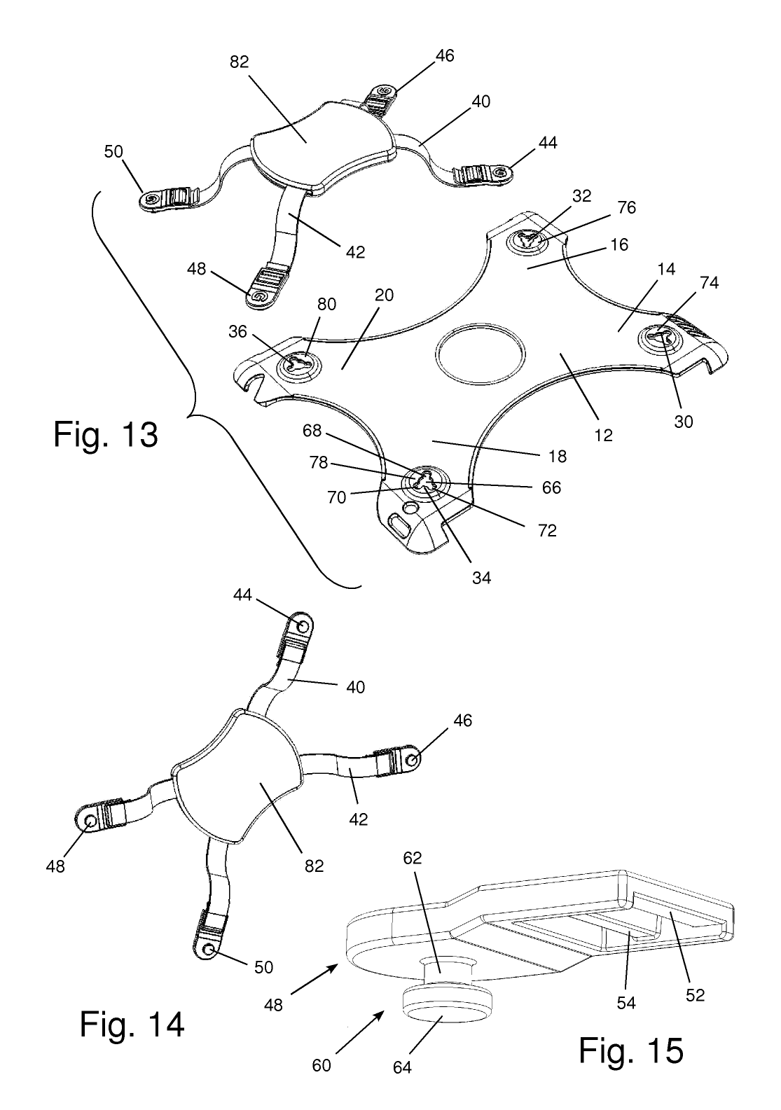

Although the base mounted strap connectors 30-36 are visible is several figures, reference is made to FIG. 13. The base mounted strap connectors 30-36 are symmetrically positioned on the base, they are symmetrically oriented and all of them have the same structural characteristics. Therefore, their characteristics are described with reference to the base mounted strap connector 34. The base mounted strap connector 34 comprises a central opening 66 in the base and a plurality of slots extending radially from the central opening and angularly spaced apart. In the preferred embodiment, the base mounted strap connector 34 has one of its radial slots, slot 68, extending toward the diagonally opposite and more distal corner of the rectangle that represents the tablet computer. The diagonal slot in each arm is essentially parallel to its diagonally extending arm. This orientation of the diagonal slots 68 retains the strap mounted connectors within the base mounted strap connectors when the straps are connected to the base in a diagonally crossed configuration because forces that are applied by the straps to the connectors as a result of a users hand being located between the base and the straps are in the direction of the slot 68.

In addition to the diagonal slots 68, each of the base mounted strap connectors also has two additional slots extending toward its nearest two sides of the rectangle. For example, the base mounted connector 34 has a slot 70 extending toward is nearest short side of the rectangle and a slot 72 extending toward its nearest long side of the rectangle. These slot orientations allow a user to connect a strap between base mounted strap connectors near opposite ends of any of the four sides and be suspended by the strap. Of course there could be more or fewer radial slots and/or the slots could have different angular orientations.

Each of the slots has a slot width near the central opening that is less than the diameter of the rod 62. This provides an interference fit between the rod 62 and the entrance to the slot. The interference fit permits the rod to be manually pushed along a slot and forced past the interference fit and then be retained against freely passing back out of the slot in the opposite direction.

As best seen in FIGS. 2 and 13, the base mounted strap connectors 30-36 are preferably formed on raised plateaus 74, 76, 78, and 80. The plateaus 74-80 protrude from the generally planar main part of the base 12 in a direction opposite from the direction of the portion of the arms that extends around and against the sides of the tablet computer. Each plateau is raised to form a space between the plateau and an attached personal computer. This space allows passage of the cap 64 of a strap mounted strap connector between the plateau and the computer as the strap mounted strap connector is slid along a selected slot of the base mounted strap connector.

A removable hand pad 82 may be attached to the straps for seating against the back of a user's hand that is inserted between the straps and the base. The hand pad 82 makes a softer and more comfortable contact with the users hand, distributes that contact over a larger area making the contact more secure and also holds together the intermediate segments of two straps. The hand pad 82 encircles intermediate segments of two straps and can be fabricated in either of two embodiments. One embodiment is a wrapable hand pad comprising a panel of flexible material having mating fasteners arranged to permit the panel to be wrapped around and encircle one or more straps that are connected to the base and fastened to itself for retaining the wrapable hand pad on the straps. The other embodiment is a fixed hand pad comprising a flattened tube of flexible material having a width in its flattened configuration that is wider than the straps. One or more straps are threaded or passed through the interior of the fixed hand pad which is then slid to surround an intermediate portion of the straps.

The plateaus 74-80, in cooperation with the strap connectors 44-50, also serve to stabilize the computer when attached to the support of the invention and resting face up on a table. As seen in the figures and particularly FIG. 12A, the top surfaces of the plateaus 74-80 are raised above the top surface of the central portion of the base 12. A part of the strap mounted strap connectors 44-50 protrudes even further above the top surfaces of the plateaus 74-80. Consequently, when the strap mounted strap connectors 44-50 are connected to the base, they function as four legs on which the base and the computer mounted to it can rest upon a table. The legs have an effective length that is the sum of the plateau height and the thickness of the portion of the strap mounted strap connectors 44-50 on the plateaus. The effective length of the legs is made greater than the thickness of the hand pad. This allows these functional legs to support the base and prevents the base from rocking or teetering on the hand pad.

Referring to FIG. 4, a ring 84 may be connected to the hand pad 82. The ring 84 is convenient for inserting through the ring a hanger, hook, clasp or other support that is mounted to a person, wall or other object in order to suspend the computer from the support. For example, the ring allows the computer to be suspended from a neck strap, shoulder strap or carabiner.

### Assembly, Operation and Use

The multi-function support of the invention is easily assembled and attached to a tablet computer. A first strap may be connected by its strap mounted strap connectors between two base mounted strap connectors that are near the opposite ends of either long side or either short side of the rectangle representing a mounted computer. Alternatively, the first strap my be connected diagonally across the back of the base 12. If desired, a second strap may be connected between the remaining two base mounted strap connectors to provide either two parallel connected straps or two diagonally crossed straps. The length of the straps can be adjusted to the user's size and preferences by conventional strap length adjusting hardware. The mating strap connectors are connected together by inserting the cap (64 in FIG. 15) of the strap mounted strap connector through the central opening (66 in FIG. 13) of the base mounted strap connector and then sliding the rod (62 in FIG. 15) along the radial slot that lies in a direction nearest the direction of the force that will be exerted by the strap on the connector when the multi-function support of the invention is in use.

To attach the computer to the base, the computer is placed face down on a flat surface. Then the base is laid on top of the back of the computer with the ends of the arms extending toward the computer and with the corners of both aligned in registration. A corner is lifted and the contacting base and computer are grasped at the corner between a finger and thumb and then squeezed or pinched together until the flange at the end of the arm is forced past the sides onto the front face of the computer to seat upon the edge of the front face. This process is then successively repeated for each of the remaining three corners.

The elastic characteristic of the base allows the arms to bend resiliently as the inwardly directed flanges are forced outwardly by the sides of the computer until they pass the sides and extend onto the front face of the computer with a a reassuring “click” or “snap” indicating that the computer is securely in place on the self-clamping base. Forming the flanges and the portion of the arms that seat against the sides of the computer at the ends of arms facilitates clamping the base onto the computer. Each arm bends more easily in a direction perpendicular to the base as the flanges are forced outwardly by the side walls. The arms at adjacent corners also bend further apart more easily in a direction parallel to their adjoining side to further facilitate passage of the flanges past the sides of the computer. In the preferred embodiment, the arms are formed by having arcuate cutouts between the arms so that each arm has a curved side. This gives a thin, sleek and smooth appearance to the base. However, the sides are not necessarily curved. The cutouts could be triangular or trapezoidal with the sides of the arms being along straight lines or with other curvatures or other polygonal cutouts.

Because the flanges at the ends of the arms of the base extend onto the face of the computer and have a thickness, the flanges protrude beyond the plane of the screen face and case of the tablet computer. As a result, when the computer is attached to the base and the combination is resting face down on a flat support surface, such as a tabletop, the computer face is raised above the support surface where the support surface won't scratch the glass or plastic screen face of the computer.

Because the arms wrap around the corners of the computer, the preferred embodiment of the invention enhances protection of the computer from concentrated impact forces at a corner, such as would occur if the computer with the attached base were dropped corner first onto a hard floor. The portion of an arm that extends over and around the corner assists in distributing the impact forces over the corner of the computer case.

The support of the invention is easily removed by grasping the edge of the assembled support and computer near a corner and between the fingers and palm of a hand. The user then pushes with the thumb against a flange in a direction outwardly and perpendicular to one of the sides of the computer. Simultaneously, the user pushes upwardly against the bottom of the computer with the fingers and then, with the thumb, pushes both parts of the right angle flange off the face of the computer.

An alternative or additional accessory is one or more straps that are considerably longer and would allow the computer to be carried over a user's shoulder or around the user's neck. The longer straps also allow a user to tighten the straps around an automobile head rest with the computer at the back of an automobile head rest where back seat passengers could, for example, watch a movie or play a game.

The four attachment points also serve as a multi-attachment mechanism by which users can attach other devices and accessories including those yet to be conceived and designed. The other devices or accessories would need only connectors that simulate the strap mounted strap connectors described above. For example, other devices or accessories can include magnets for securing the computer to a ferromagnetic surface, mobile stands designed to hold the tablet PC in an upright position when placed down on a flat surface, reinforced cord attachments designed to allow a user to securely hang a tablet PC around the neck, interchangeable straps that allow a user to attach a tablet PC to a backpack or other piece of luggage or an accessory bag or enclosure or pouch attached to the tablet PC designed to store and secure tablet PC accessories such as charging cables, headphones, speakers or other accompanying pieces.

This detailed description in connection with the drawings is intended principally as a description of the presently preferred embodiments of the invention, and is not intended to represent the only form in which the present invention may be constructed or utilized. The description sets forth the designs, functions, means, and methods of implementing the invention in connection with the illustrated embodiments. It is to be understood, however, that the same or equivalent functions and features may be accomplished by different embodiments that are also intended to be encompassed within the spirit and scope of the invention and that various modifications may be adopted without departing from the invention or scope of the following claims.

1. A multi-function support for a tablet personal computer, the computer having a back, sides and a front face, the support comprising:
(a) an elastically deformable base configured to seat against the back, the base further including a plurality of arms, each arm extending outwardly from a central portion of the base toward the sides and extending around and against spaced apart portions of the sides, the arms each having an inwardly directed flange extending onto the edge of the face for retaining the computer against the base, the base further including a plurality of releasable, base mounted strap connectors at spaced-apart attachment points on the base; and
(b) at least one strap having a length greater than the distance between attachment points, the strap having at least two, strap mounted strap connectors that mate with the base mounted strap connectors and detachably attach the strap to the base.

2. A multi-function support in accordance with claim 1 wherein the base has four arms diagonally extending toward four corners of a rectangle, the face engaging flanges of each arm extending along a right angle for engaging the face around each corner of the tablet computer.

3. A multi-function support in accordance with claim 2 wherein:
(a) each of the strap mounted strap connectors comprises a T-shaped post having a rod connected to a strap at one end and having a cap at the opposite end, the cap having a greater width than the rod; and
(b) each of the base mounted, strap connectors comprises a central opening in the base and a plurality of slots extending radially from the central opening, the slots having a width near the central opening that is less than the diameter of the rod for permitting the rod to be manually pushed and frictionally passed along a slot and be retained against freely passing out of the slot.

4. A multi-function support in accordance with claim 3 wherein there are at least two of said straps and at least four of said strap mounted connectors, one spaced from but near the end of each arm.

5. A multi-function support in accordance with claim 4 wherein each of the base mounted strap connectors has one of its radial slots extending toward a diagonally opposite corner of the rectangle for secure attachment of the straps in a diagonally crossed configuration.

6. A multi-function support in accordance with claim 5 wherein each of the base mounted strap connectors also has slots extending toward its nearest sides of the rectangle.

7. A multi-function support in accordance with claim 6 wherein the base mounted strap connectors are formed on a raised plateau that protrudes in a direction opposite from the direction of the portion of the arms that extends around the sides, each plateau being raised to allow passage of the cap of a strap mounted strap connector between the plateau and the computer.

8. A multi-function support in accordance with claim 6 and further comprising a wrapable hand pad comprising a panel of flexible material having mating fasteners arranged to permit the panel to be wrapped around and encircle one or more straps that are connected to the base and fastened to itself for retaining the wrapable hand pad on the straps.

9. A multi-function support in accordance with claim 8 and further comprising a ring connected to the hand pad for insertion through the ring of a support for suspending the computer from the support.

10. A multi-function support in accordance with claim 6 and further comprising a fixed hand pad comprising a flattened tube of flexible material having a width in its flattened configuration that is wider than the straps to permit one or more straps to be passed through the interior of the fixed hand pad.

11. A multi-function support in accordance with claim 10 and further comprising a ring connected to the hand pad for insertion through the ring of a support for suspending the computer from the support.
